(19) United States
(12) Patent Application Publication
(10) Pub. No.: US 2024/0061279 A1
(43) Pub. Date: Feb. 22, 2024

(54) OPTICAL SEMICONDUCTOR DEVICE

(71) Applicant: Mitsubishi Electric Corporation, Tokyo (JP)

(72) Inventor: Yoshimichi MORITA, Tokyo (JP)

(73) Assignee: Mitsubishi Electric Corporation, Tokyo (JP)

(21) Appl. No.: 18/260,599

(22) PCT Filed: May 13, 2021
(86) PCT No.: PCT/JP2021/018294

§ 371 Date: Jul. 6, 2023

(51) Int. Cl. G02F 1/01; H01S 5/00; H01S 5/40; H01S 5/042

(52) U.S. Cl. CPC G02F 1/0121; H01S 5/0085; H01S 5/4087; H01S 5/042; H01S 5/12

(57) ABSTRACT

An optical semiconductor device according to the present disclosure includes at least one laser, a plurality of EA modulators to which an output of the laser is connected on an input side and which have absorption peak wavelengths different from each other, a multiplexer to which outputs of the plurality of EA modulators are connected on an input side and to which a waveguide is connected on an output side, a temperature detector configured to detect a temperature of the laser or the plurality of EA modulators and a selection control circuitry configured to switch an EA modulator to operate among the plurality of EA modulators in accordance with a detected temperature of the temperature detector.

### FIELD

The present disclosure relates to an optical semiconductor device.

### BACKGROUND

PTL 1 discloses a semiconductor laser device. This semiconductor laser device includes a plurality of DFB lasers with different oscillation wavelengths, a multiplexer that couples outputs of the plurality of DFB lasers, and an EA modulator that modulates light output from the multiplexer. Further, the semiconductor laser device includes a temperature detector that measures a temperature, and a laser selection control circuitry that selects and switches a DFB laser to operate among the plurality of DFB lasers on the basis of the temperature detected by the temperature detector.

### CITATION LIST

### Patent Literature

[PTL 1] JP 2020-109800 A

### SUMMARY

### Technical Problem

An electroabsorption modulated laser (EML) is constituted with a distributed feedback (DFB) laser and an electroabsorption modulator (EA modulator). A difference between an oscillation wavelength λDFB of the DFB laser and an absorption peak wavelength λEA of the EA modulator is referred to as a detuning amount Δλ. The detuning amount Δλ is typically an important parameter that influences performance as a laser diode (LD) for communication. Typically, there is a trade-off relationship via Δλ between an optical output and an extinction ratio which are main characteristics of the EML. Normally, a value of Δλ is determined so that balance between the optical output and the extinction ratio becomes optimal.

However, typically, temperature dependence of the oscillation wavelength λDFB is largely different from temperature dependence of the absorption peak wavelength λEA. Thus, if a temperature of the device fluctuates, Δλ may largely fluctuate. There is therefore a possibility that balance between the optical output and the extinction ratio may be lost.

In PTL 1, an LD to operate is switched in accordance with a temperature. By this means, the oscillation wavelength λDFB is caused to follow large temperature change of the absorption peak wavelength λEA. However, in PTL 1, a range of a value taken by the oscillation wavelength λDFB may be wide. Thus, there is a possibility that in a case where strict wavelength standards are required, the semiconductor laser device in PTL 1 cannot be employed.

The present disclosure is directed to providing an optical semiconductor device that can achieve a reduced range in which an oscillation wavelength changes.

### Solution to Problem

An optical semiconductor device according to the present disclosure includes at least one laser, a plurality of EA modulators to which an output of the laser is connected on an input side and which have absorption peak wavelengths different from each other, a multiplexer to which outputs of the plurality of EA modulators are connected on an input side and to which a waveguide is connected on an output side, a temperature detector configured to detect a temperature of the laser or the plurality of EA modulators and a selection control circuitry configured to switch an EA modulator to operate among the plurality of EA modulators in accordance with a detected temperature of the temperature detector.

### Advantageous Effects of Invention

In an optical semiconductor device according to the present disclosure, an EA modulator to operate is switched among a plurality of EA modulators in accordance with a temperature. It is therefore possible to reduce a range in which an oscillation wavelength changes.

### BRIEF DESCRIPTION OF DRAWINGS

FIG. 1 is a block diagram illustrating a configuration of an optical semiconductor device according to a first embodiment.

FIG. 2 is a view illustrating an aspect of change of the oscillation wavelength λDFB and the absorption peak wavelength λEA according to the first embodiment.

FIG. 3 is a view illustrating an aspect of change of the oscillation wavelength λDFB and the absorption peak wavelength λEA according to a first comparative example.

FIG. 4 is a view illustrating an aspect of change of the oscillation wavelength λDFB and the absorption peak wavelength λEA according to a second comparative example.

FIG. 5 is a flowchart for explaining operation of the optical semiconductor device according to the first embodiment.

FIG. 6 is a view for explaining a look-up table according to the first embodiment.

FIG. 7 is a block diagram illustrating a configuration of an optical semiconductor device according to a second embodiment.

FIG. 8 is a view illustrating an aspect of change of the oscillation wavelength λDFB and the absorption peak wavelength λEA according to the second embodiment.

FIG. 9 is a flowchart for explaining operation of the optical semiconductor device according to the second embodiment.

FIG. 10 is a view for explaining a look-up table according to the second embodiment.

FIG. 11 is a block diagram illustrating a configuration of an optical semiconductor device according to a third embodiment.

FIG. 12 is a block diagram illustrating a configuration of an optical semiconductor device according to a fourth embodiment.

FIG. 13 is a cross-sectional view obtained by cutting FIG. 12 along a line A-A.

FIG. 14 is a cross-sectional view obtained by cutting FIG. 12 along a line B-B.

### DESCRIPTION OF EMBODIMENTS

An optical semiconductor device according to each embodiment is described with reference to drawings. Identical or corresponding constitutional elements are given the same reference numerals, and the repeated description of such constitutional elements may be omitted.

### First Embodiment

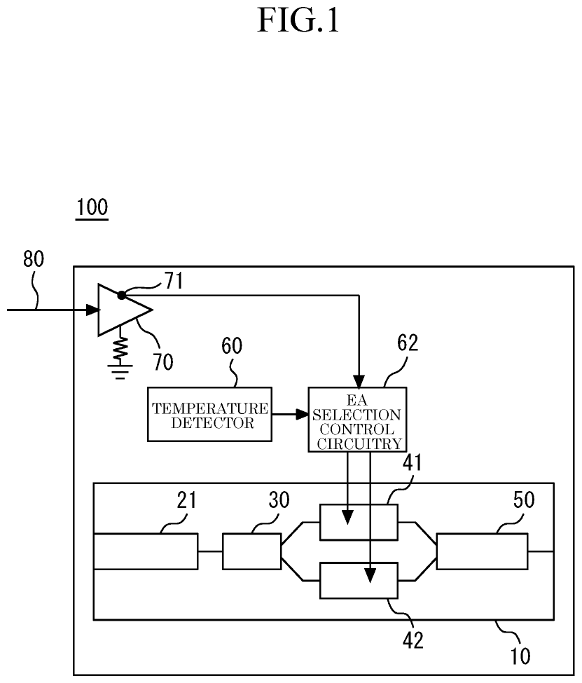

FIG. 1 is a block diagram illustrating a configuration of an optical semiconductor device 100 according to a first embodiment. The optical semiconductor device 100 is an optical transmitter. The optical semiconductor device 100 is also referred to as an uncooled EML optical transmitter. The optical semiconductor device 100 includes an EML. The EML is also referred to as a DFB laser with an electroabsorption modulator.

The optical semiconductor device 100 includes one laser 21, and a plurality of EA modulators 41 and 42 to which an output of the laser 21 is connected on an input side. The laser 21 is a DFB laser. The EA modulators 41 and 42 have absorption peak wavelengths different from each other. While FIG. 1 illustrates two EA modulators 41 and 42, three or more EA modulators may be provided. A demultiplexer 30 connects the laser 21 and the plurality of EA modulators 41 and 42. The demultiplexer 30 demultiplexes output light of the laser 21 and inputs the demultiplexed output light to the plurality of EA modulators 41 and 42. Outputs of the plurality of EA modulators 41 and 42 are connected on an input side of a multiplexer 50, and a waveguide is connected on an output side of the multiplexer 50. As the demultiplexer 30 and the multiplexer 50, for example, a multi-mode interference (MMI) can be used.

In a semiconductor optical integrated device 10, the laser 21, the demultiplexer 30, the EA modulators 41 and 42, the multiplexer 50 and the waveguide are monolithically integrated on the same substrate. A temperature detector 60 detects a temperature of the laser 21 or the plurality of EA modulators 41 and 42. The temperature detector 60 may detect a temperature of the semiconductor optical integrated device 10 or may detect a temperature of the substrate on which the laser 21 and the plurality of EA modulators 41 and 42 are formed.

An EA selection control circuitry 62 switches an EA modulator to operate among the plurality of EA modulators 41 and 42 in accordance with a detected temperature Tc of the temperature detector 60. An EA driver 70 outputs a modulation signal for modulating the EA modulators 41 and 42 in accordance with a signal 80 from outside. The EA selection control circuitry 62 outputs the modulation signal output from the EA driver 70 to one of the plurality of EA modulators 41 and 42 in accordance with the detected temperature Tc.

An operation temperature range of the optical semiconductor device 100 is, for example, the detected temperature Tc of the temperature detector 60=−40° C. to +90° C. The EA selection control circuitry 62, for example, selects the EA modulator 41 when the detected temperature Tc is from −40° C. to +25° C. and selects the EA modulator 42 when the detected temperature Tc is from +25° C. to +90° C. It is designed that an oscillation wavelength λDFB of the laser 21 becomes, for example, 1310 nm at +25° C. It is designed that an absorption peak wavelength λEA1 of the EA modulator 41 becomes, for example, 1258 nm at +25° C. The absorption peak wavelength is also referred to as an absorption end wavelength. It is designed that an absorption peak wavelength λEA2 of the EA modulator 42 becomes, for example, 1232 nm at +25° C.

In this manner, the EA modulator 42 has the absorption peak wavelength λEA smaller than that of the EA modulator 41 at the same temperature. The EA selection control circuitry 62 causes the EA modulator 41 to operate when the detected temperature Tc is lower than a threshold determined in advance and causes the EA modulator 42 to operate when the detected temperature Tc is higher than the threshold. Here, causing the EA modulator to operate indicates outputting a modulation signal to the EA modulator. Further, in the present embodiment, the threshold of the detected temperature Tc is, for example, +25° C.

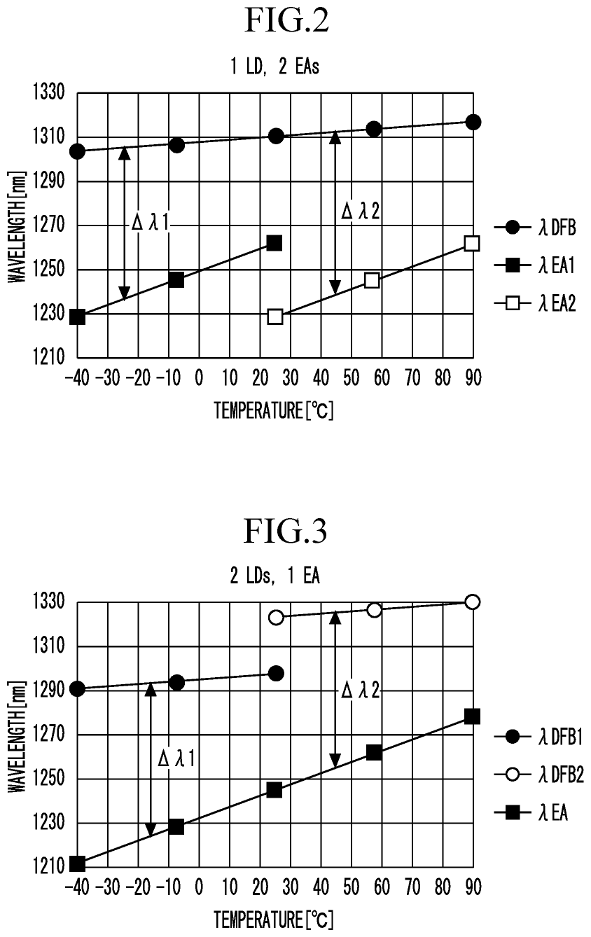

FIG. 2 is a view illustrating an aspect of change of the oscillation wavelength λDFB and the absorption peak wavelength λEA according to the first embodiment. The oscillation wavelength λDFB and the absorption peak wavelength λEA, for example, fluctuate with respect to temperature change respectively at 0.1 nm/° C. and 0.5 nm/° C. In this manner, a fluctuation rate of the absorption peak wavelength λEA with respect to the temperature is larger than a fluctuation rate of the oscillation wavelength λDFB.

The oscillation wavelength λDFB fluctuates in a range from 1303.5 to 1310 nm at −40° C. to +25° C., and a fluctuation width is 6.5 nm. Further, the absorption peak wavelength λEA1 fluctuates in a range from 1225.5 to 1258 nm at −40° C. to +25° C., and a fluctuation width is 32.5 nm. In this event, a detuning amount Δλ1 which is a difference between the oscillation wavelength λDFB and the absorption peak wavelength λEA1 fluctuates in a range from 52 to 78 nm at −40° C. to +25° C., and a fluctuation width is 26 nm.

λDFB fluctuates in a range from 1310 to 1316.5 nm at +25° C. to +90° C., and a fluctuation width is 6.5 nm. Further, the absorption peak wavelength λEA2 fluctuates in a range from 1232 to 1264.5 nm at +25° C. to +90° C., and a fluctuation width is 32.5 nm. In this event, a detuning amount Δλ2 which is a difference between the oscillation wavelength λDFB and the absorption peak wavelength λEA2 fluctuates in a range from 52 to 78 nm at +25° C. to +90° C., and a fluctuation width is 26 nm. As a result, λDFB fluctuates in a range from 1303.5 to 1316.5 nm at the entire temperature range from −40° C. to 90° C., and a fluctuation width is 13 nm.

FIG. 3 is a view illustrating an aspect of change of the oscillation wavelength λDFB and the absorption peak wavelength λEA according to a first comparative example. In the first comparative example, one EA modulator is provided, and a laser to operate between two lasers with different oscillation wavelengths λDFB is switched in accordance with a temperature. It is assumed here that the absorption peak wavelength λEA of only one EA modulator that is mounted is fixed at 1245 nm at 25° C. Further, it is designed that an oscillation wavelength λDFB1 of a first laser becomes 1297 nm at 25° C. Still further, it is designed that an oscillation wavelength λDFB2 of a second laser becomes 1323 nm at 25° C. The oscillation wavelength λDFB and the absorption peak wavelength λEA fluctuate with respect to temperature change respectively at 0.1 nm/° C. and 0.5 nm/° C.

In the first comparative example, the oscillation wavelength λDFB1 fluctuates in a range from 1290.5 to 1297 nm at −40° C. to 25° C., and a fluctuation width is 6.5 nm. The absorption peak wavelength λEA fluctuates in a range from 1212.5 to 1245 nm, and a fluctuation width is 32.5 nm. In this event, a detuning amount Δλ1 fluctuates in a range from 52 to 78 nm, and a fluctuation width is 26 nm.

The oscillation wavelength λDFB2 fluctuates in a range from 1323 to 1329.5 nm at +25° C. and +90° C., and a fluctuation width is 6.5 nm. The absorption peak wavelength λEA fluctuates in a range from 1245 to 1277.5 nm, and a fluctuation width is 32.5 nm. A detuning amount Δλ2 fluctuates in a range from 52 and 78 nm, and a fluctuation width is 26 nm.

In the first comparative example, a fluctuation width of the detuning amount Δλ at the entire temperature range from −40° C. to +90° C. is 26 nm, which is the same as in the present embodiment. On the other hand, a fluctuation width of the oscillation wavelength λDFB is 39 nm, which is three times as that in the present embodiment. The temperature change of the absorption peak wavelength λEA is larger than the temperature change of the oscillation wavelength λDFB. Thus, if the laser is switched so as to follow the temperature change of the absorption peak wavelength λEA, the fluctuation width of the oscillation wavelength λDFB becomes larger. In this manner, in a case where the laser to operate is switched to reduce the fluctuation width of the detuning amount Δλ, the fluctuation width of the oscillation wavelength λDFB becomes large. Thus, the present embodiment has advantages particularly in a case where strict wavelength standards are required.

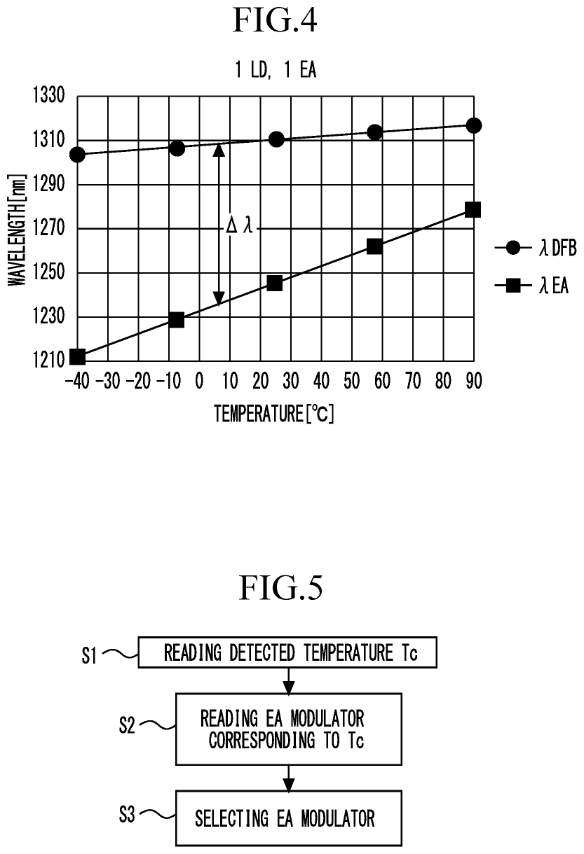

FIG. 4 is a view illustrating an aspect of change of the oscillation wavelength λDFB and the absorption peak wavelength λEA according to a second comparative example. In the second comparative example, one laser and one EA modulator are provided. In this event, the fluctuation width of the detuning amount Δλ at the entire temperature range from −40° C. to +90° C. is 52 nm, which is larger than that in the present embodiment. Further, the fluctuation width of the oscillation wavelength λDFB is 13 nm, which is equal to that in the present embodiment.

In this manner, a range of a value that can be taken by the detuning amount Δλ is narrower in the present embodiment and in the first comparative example. Further, a range of a value taken by the oscillation wavelength λDFB is narrower in the present embodiment and in the second comparative example. In other words, it can be said that the present embodiment is an optimal configuration among the above-described three forms.

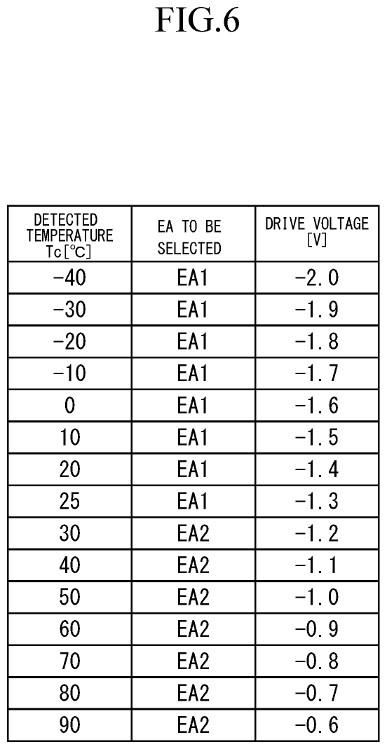

FIG. 5 is a flowchart for explaining operation of the optical semiconductor device 100 according to the first embodiment. FIG. 6 is a view for explaining a look-up table according to the first embodiment. Algorithm of selecting the EA modulator and causing the EA modulator to operate will be described using FIGS. 5 and 6.

The temperature detector 60 is designed to output the detected temperature Tc, for example, in units of 10° C. The EA selection control circuitry 62 includes a storage unit. The EA selection control circuitry 62 stores a look-up table that associates discrete detected temperatures Tc and the EA modulator to be selected in the storage unit. The EA selection control circuitry 62 reads the detected temperature Tc from the temperature detector 60 (step 1). If the detected temperature Tc is transmitted from the temperature detector 60, the EA selection control circuitry 62 reads the EA modulator corresponding to the detected temperature Tc from the look-up table (step 2). In the look-up table indicated in FIG. 6, EA1 indicates the EA modulator 41, and EA2 indicates the EA modulator 42. Then, the EA selection control circuitry 62 selects and drives the EA modulator corresponding to the detected temperature Tc (step 3).

The EA selection control circuitry 62 may switch a drive voltage of the EA modulator in accordance with the detected temperature Tc. The look-up table indicated in FIG. 6 includes information on a drive voltage corresponding to the detected temperature Tc. In this manner, the EA selection control circuitry 62 may read the drive voltage corresponding to the detected temperature Tc and drive the EA modulator with the read drive voltage. In the example indicated in FIG. 6, an absolute value of the drive voltage is set so as to be greater as the detected temperature Tc is lower. By finely adjusting the drive voltage as well as selecting the EA modulator, fluctuation of characteristics by the temperature can be further reduced.

In this manner, in the present embodiment, by switching the EA modulator among the plurality of EA modulators, the temperature change of the absorption peak wavelength λEA is caused to follow the temperature change of the oscillation wavelength λDFB which is smaller than the temperature change of the absorption peak wavelength λEA. This can reduce a range in which the oscillation wavelength λDFB changes compared to the first comparative example in which the laser is switched among the plurality of lasers. It is therefore possible to use the optical semiconductor device 100 also in a case where strict wavelength standards are required.

Further, in the present embodiment, it is possible to reduce the fluctuation width of the detuning amount Δλ while reducing the fluctuation width of the oscillation wavelength λDFB with respect to temperature change. It is therefore possible to implement uncooled operation in a wide temperature range from −40° C. to +90° C. required for a semiconductor laser to be used outdoors.

Further, in the present embodiment, the EA selection control circuitry 62 causes the EA modulator 41 to operate when the detected temperature Tc is in a first temperature range and causes the EA modulator 42 to operate when the detected temperature Tc is in a second temperature range. In the example indicated in FIG. 2, the first temperature range is from −40° C. to +25° C., and the second temperature range is from +25° C. to +90° C. In this event, a range in which the absorption peak wavelength λEA1 of the EA modulator 41 changes in the first temperature range at least partially overlaps a range in which the absorption peak wavelength λEA2 of the EA modulator 42 changes in the second temperature range. This can further reduce the fluctuation width of the detuning amount Δλ. The range in which the absorption peak wavelength λEA1 changes in the first temperature range and the range in which the absorption peak wavelength λEA2 changes in the second temperature range may be set so that, for example, the fluctuation width of the detuning amount Δλ becomes smaller than that in the second comparative example.

While in the present embodiment, an example where two EA modulators are integrated on the same substrate is described, three or more EA modulators with different absorption peak wavelengths λEA may be integrated on the same substrate, and one of the EA modulators may be selected in accordance with a temperature. This narrows a temperature range to be covered by each EA modulator. It is therefore possible to further reduce the fluctuation width of the detuning amount Δλ in the entire temperature range from −40° C. to +90° C. Further, by providing three or more EA modulators, it is possible to implement uncooled operation in a further larger temperature range with a fluctuation width of the detuning amount Δλ equal to that in a case where two EA modulators are provided.

These modifications can be applied, as appropriate, to optical semiconductor devices according to the following embodiments. Note that the optical semiconductor devices according to the following embodiments are similar to that of the first embodiment in many respects, and thus differences between the optical semiconductor devices according to the following embodiments and that of the first embodiment will be mainly described below.

### Second Embodiment

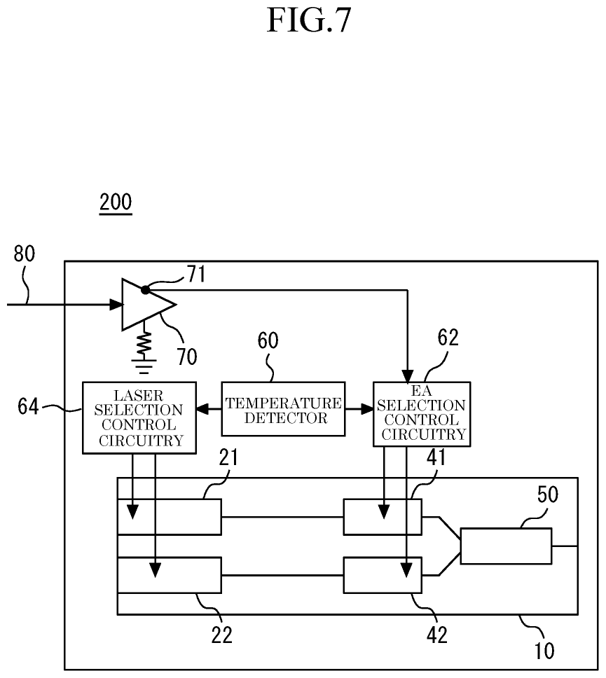

FIG. 7 is a block diagram illustrating a configuration of an optical semiconductor device 200 according to a second embodiment. The optical semiconductor device 200 according to the present embodiment is different from the optical semiconductor device 100 in that a plurality of lasers 21 and 22 with different oscillation wavelengths λDFB are provided. Outputs of the plurality of lasers 21 and 22 are respectively connected on input sides of the plurality of EA modulators 41 and 42. Two lasers 21 and 22 are integrated in the semiconductor optical integrated device 10.

Further, the optical semiconductor device 200 includes a laser selection control circuitry 64 and the EA selection control circuitry 62 as the selection control circuitry. The laser selection control circuitry 64 supplies a drive current to one of the plurality of lasers 21 and 22 in accordance with the detected temperature Tc and causes the one of the lasers 21 and 22 to operate. The EA selection control circuitry 62 supplies a drive voltage to one of the plurality of EA modulators 41 and 42 in accordance with the detected temperature Tc and causes the one of the EA modulators 41 and 42 to operate. In this manner, the selection control circuitry switches the laser to operate among the plurality of lasers 21 and 22 and switches the EA modulator to operate among the plurality of EA modulators in accordance with the detected temperature Tc. Other configurations are the same as the configurations in the first embodiment.

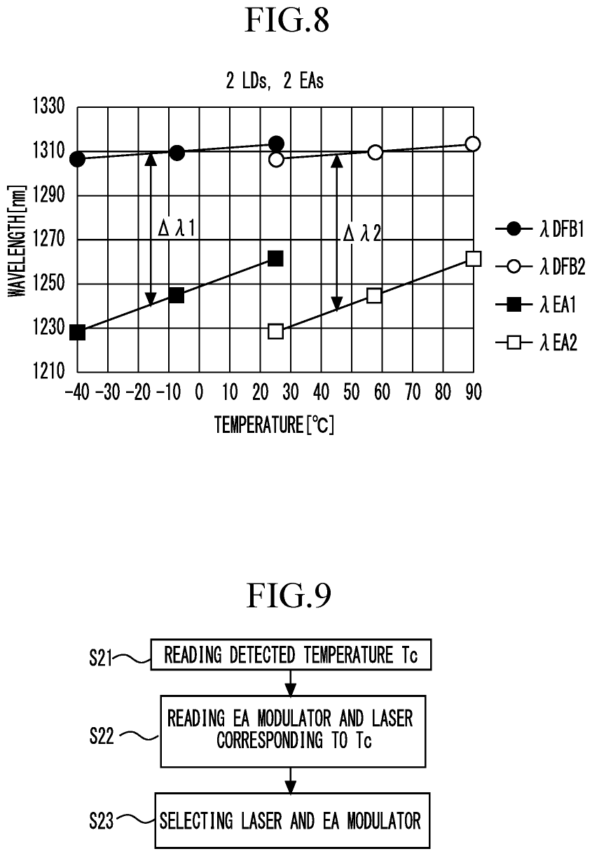

FIG. 8 is a view illustrating an aspect of change of the oscillation wavelength λDFB and the absorption peak wavelength λEA according to the second embodiment. An operation temperature range of the optical semiconductor device 200 is, for example, the detected temperature Tc of the temperature detector 60=−40° C. to +90° C. By the operation of the EA selection control circuitry 62 and the laser selection control circuitry 64, in a case where the detected temperature Tc is from −40° C. to +25° C., the laser 21 and the EA modulator 41 are selected, and in a case where the detected temperature Tc is from +25° C. to +90° C., the laser 22 and the EA modulator 42 are selected.

It is designed that the oscillation wavelength λDFB1 of the laser 21 becomes 1310 nm at −7.5° C. which is a center temperature of a temperature range from −45° C. to +25° C. that is to be covered. It is designed that the oscillation wavelength λDFB2 of the laser 22 becomes 1310 nm at +57.5° C. which is a center temperature of a temperature range from +25° C. to +90° C. that is to be covered. It is designed that the absorption peak wavelength λEA1 of the EA modulator 41 becomes 1245 nm at −7.5° C. which is a center temperature of a temperature range from −45° C. to +25° C. that is to be covered. It is designed that the absorption peak wavelength λEA2 of the EA modulator 42 becomes 1245 nm at +57.5° C. which is a center temperature of the temperature range from +25° C. to +90° C. that is to be covered.

The laser 22 has the oscillation wavelength λDFB smaller than that of the laser 21 at the same temperature. The laser selection control circuitry 64 causes the laser 21 to operate when the detected temperature Tc is lower than a threshold determined in advance and causes the laser 22 to operate when the detected temperature Tc is higher than the threshold. The threshold is, for example, +25° C.

The oscillation wavelength λDFB and the absorption peak wavelength λEA, for example, fluctuate with respect to temperature change respectively at 0.1 nm/° C. and 0.5 nm/° C. The oscillation wavelength λDFB1 fluctuates in a range from 1306.75 to 1313.25 nm at −40° C. to +25° C., and a fluctuation width is 6.5 nm. The absorption peak wavelength λEA1 fluctuates in a range from 1228.75 to 1261.25 nm, and a fluctuation width is 32.5 nm. The detuning amount Δλ1 fluctuates in a range from 52 to 78 nm, and a fluctuation width is 26 nm.

At +25° C. to +90° C., the oscillation wavelength λDFB2 fluctuates in a range from 1306.75 to 1313.25 nm, and a fluctuation width is 6.5 nm. The absorption peak wavelength λEA2 fluctuates in a range from 1228.75 to 1261.25 nm, and a fluctuation width is 32.5 nm. The detuning amount Δλ2 fluctuates in a range from 52 to 78 nm, and a fluctuation width is 26 nm.

The oscillation wavelength λDFB in the entire temperature range from −40° C. to +90° C. fluctuates in a range from 1306.75 to 1313.25 nm, and a fluctuation width is 6.5 nm. Thus, in the present embodiment, the fluctuation width of the oscillation wavelength λDFB can be reduced to half of that in the first embodiment. Further, the fluctuation width of the detuning amount Δλ is equal to that in the first embodiment.

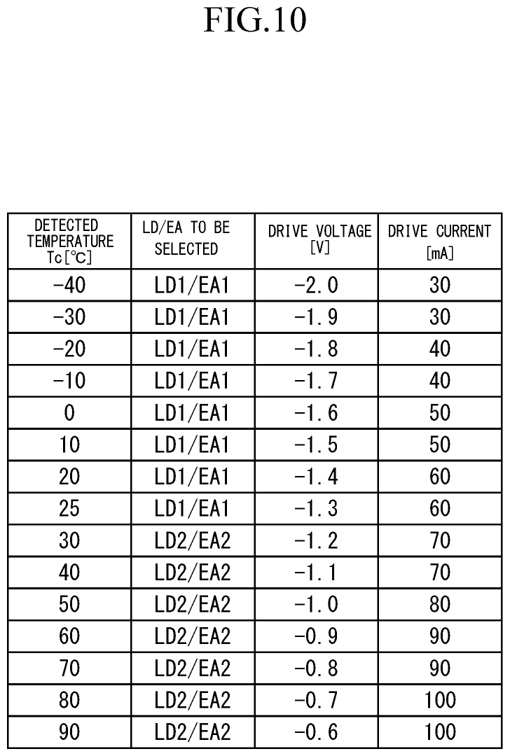

FIG. 9 is a flowchart for explaining operation of the optical semiconductor device 200 according to the second embodiment. FIG. 10 is a view for explaining a look-up table according to the second embodiment. Algorithm of selecting the laser and the EA modulator and causing the laser and the EA modulator to operate will be indicated using FIGS. 9 and 10. Each of the EA selection control circuitry 62 and the laser selection control circuitry 64 stores a look-up table that associates discrete detected temperatures Tc and the laser and the EA modulator to be selected as indicated in FIG. 10.

The EA selection control circuitry 62 and the laser selection control circuitry 64 read the detected temperature Tc (step 21). Then, the EA selection control circuitry 62 and the laser selection control circuitry 64 read the DFB laser and the EA modulator corresponding to the detected temperature Tc from the look-up table (step 22). Note that in the look-up table indicated in FIG. 10, LD1 indicates the laser 21, LD2 indicates the laser 22, EA1 indicates the EA modulator 41, and EA2 indicates the EA modulator 42. Then, the EA selection control circuitry 62 and the laser selection control circuitry 64 select and drive the laser and the EA modulator corresponding to the detected temperature Tc (step 23).

The laser selection control circuitry 64 may switch a drive current of the laser in accordance with the detected temperature Tc. The EA modulator 41 may switch a drive voltage of the EA modulator in accordance with the detected temperature Tc. The look-up table indicated in FIG. 10 includes information on the drive current of the laser and the drive voltage of the EA modulator corresponding to the detected temperature Tc. In this manner, the laser selection control circuitry 64 may read the drive current corresponding to the detected temperature Tc and drive the laser with the read drive current. Further, the EA selection control circuitry 62 may read the drive voltage corresponding to the detected temperature Tc and drive the EA modulator with the read drive voltage. In the example indicated in FIG. 10, the drive current is set higher as the detected temperature Tc is higher. Further, an absolute value of the drive voltage is set greater as the detected temperature Tc is lower. By finely adjusting the drive current or the EA drive voltage as well as selecting the laser and the EA modulator, fluctuation of characteristics by the temperature can be further reduced.

In this manner, in the present embodiment, by a plurality of lasers 21 and 22 being provided, the fluctuation width of the oscillation wavelength λDFB can be made smaller than that in the first embodiment. It is therefore possible to use the optical semiconductor device 200 also in a case where strict wavelength standards are required.

Further, in the present embodiment, the laser selection control circuitry 64 causes the laser 21 to operate when the detected temperature Tc is in the first temperature range and causes the laser 22 to operate when the detected temperature Tc is in the second temperature range. In the example indicated in FIG. 8, the first temperature range is from −40° C. to +25° C., and the second temperature range is from +25° C. to 90° C. In this event, a range in which the oscillation wavelength λDFB1 of the laser 21 changes in the first temperature range at least partially overlaps a range in which the oscillation wavelength λDFB2 of the laser 22 changes in the second temperature range. This can make the fluctuation width of the oscillation wavelength λDFB smaller in the entire temperature range than that in the first embodiment.

An example where two lasers and two EA modulators are integrated on the same substrate has been described above. The present disclosure is not limited to this, and three or more lasers with different oscillation wavelengths λDFB and three or more EA modulators with different absorption peak wavelengths λEA may be integrated on the same substrate, and one of the lasers and one of the EA modulators may be selected in accordance with a temperature. This narrows the temperature range to be covered by each laser and each EA modulator. It is therefore possible to further reduce the fluctuation width of the detuning amount Δλ in the entire temperature range from −40° C. to +90° C. Further, by providing three or more lasers or EA modulators, it is possible to implement uncooled operation in a further larger temperature range with the fluctuation width of the detuning amount Δλ equal to that in a case where two lasers and two EA modulators are provided.

Further, a temperature at which the EA modulator is switched between the EA modulators 41 and 42 may be different from a temperature at which the laser is switched between the lasers 21 and 22.

### Third Embodiment

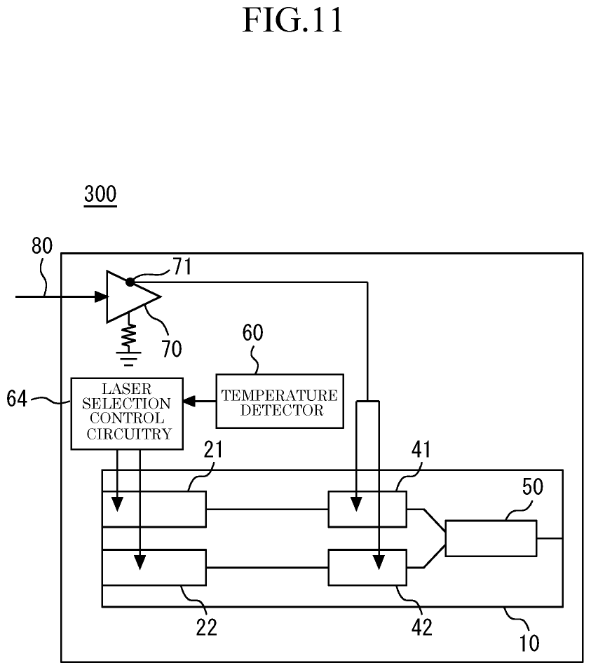

FIG. 11 is a block diagram illustrating a configuration of an optical semiconductor device 300 according to a third embodiment. The optical semiconductor device 300 includes the plurality of EA modulators 41 and 42, and the plurality of lasers 21 and 22. Further, the EA selection control circuitry 62 is not provided in the present embodiment. A drive voltage is supplied to each of the plurality of EA modulators 41 and 42 from the EA driver 70. The EA driver 70 includes an output terminal 71 that outputs a drive voltage. The plurality of EA modulators 41 and 42 are connected in parallel to the output terminal 71 of the EA driver 70. Other configurations are similar to the configurations in the second embodiment.

In the optical semiconductor device 300, the drive voltage of the EA driver is constantly supplied to the EA modulators 41 and 42 regardless of the detected temperature Tc. However, an optical signal is not output from the EA modulator without an optical input from the subsequent laser. Thus, in a case where the laser 21 is selected by the laser selection control circuitry 64, an optical signal is output only from the EA modulator 41. In a similar manner, in a case where the laser 22 is selected by the laser selection control circuitry 64, an optical signal is output only from the EA modulator 42. In this manner, the selection control circuitry of the present embodiment indirectly switches the EA modulator to operate by switching the laser to operate.

In the present embodiment, the EA selection control circuitry 62 is not provided. It is therefore possible to switch the EA modulator with an inexpensive configuration compared to the second embodiment. However, two EA modulators 41 and 42 are connected in parallel to the output terminal 71 of one EA driver 70, and thus, capacity increases. Thus, there is a possibility that a modulation bandwidth may degrade compared to the second embodiment.

### Fourth Embodiment

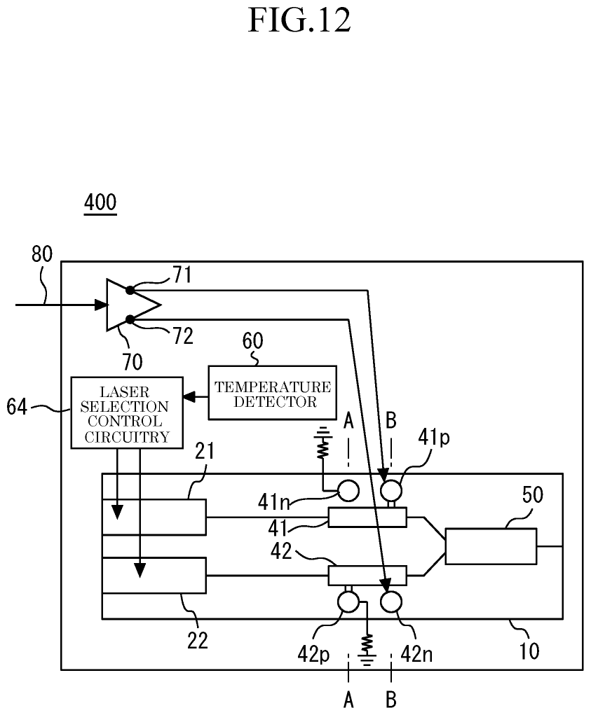

FIG. 12 is a block diagram illustrating a configuration of an optical semiconductor device 400 according to a fourth embodiment. In the first to the third embodiments, only one of a positive phase component and a reverse phase component of a differential output terminal of the EA driver 70 is utilized. In contrast, the present embodiment is different from the third embodiment in that the other component is also utilized.

The EA driver 70 outputs a positive phase signal and a reverse phase signal as the drive voltage. For example, the positive phase signal is output from the output terminal 71, and the reverse phase signal is output from an output terminal 72. The positive phase signal is applied to one of the plurality of EA modulators 41 and 42, and the reverse phase signal is applied to the other. In the present embodiment, as one example, the positive phase signal is input to the EA modulator 41, and the reverse phase signal is input to the EA modulator 42. In this event, in a case where the EA modulators 41 and 42 have the same polarity, 1 and 0 of the optical signal to be output are inverted depending on the EA modulator to be selected. Thus, the polarity of the EA modulator 41 and the polarity of the EA modulator 42 are preferably inverted in advance.

In the semiconductor optical integrated device 10 of the present embodiment, a p-type electrode pad 41p and an n-type electrode pad 41n of the EA modulator 41, and a p-type electrode pad 42p and an n-type electrode pad 42n of the EA modulator 42 are provided on a chip surface. The output terminal 71 which is a positive phase output terminal is connected to the p-type electrode pad 41p. Further, the output terminal 72 which is a reverse phase output terminal is connected to the n-type electrode pad 42n. By this means, the positive phase signal is applied to the p-type electrode pad 41p of the EA modulator 41, and the reverse phase signal is applied to the n-type electrode pad 42n of the EA modulator 42. Thus, the same optical signal is output from the EA modulators 41 and 42.

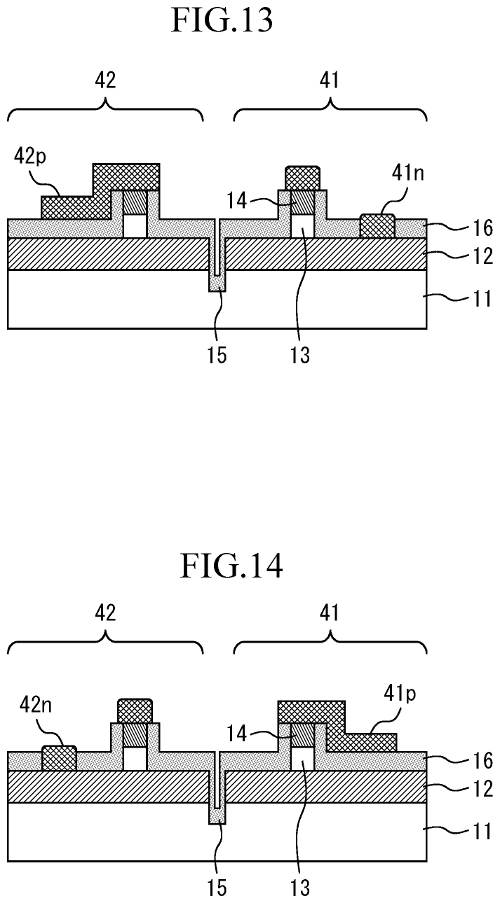

FIG. 13 is a cross-sectional view obtained by cutting FIG. 12 along a line A-A. FIG. 14 is a cross-sectional view obtained by cutting FIG. 12 along a line B-B. Each of the EA modulators 41 and 42 includes a semi-insulating InP substrate 11, and an n-type InP clad layer 12, a light-absorbing layer 13 and a p-type InP clad layer 14 which are sequentially laminated on the semi-insulating InP substrate 11. The EA modulators 41 and 42 are electrically separated from each other by a trench 15 that reaches the semi-insulating InP substrate 11 from the chip surface.

An upper surface of the n-type InP clad layer 12 and side surfaces of the light-absorbing layer 13 and the p-type InP clad layer 14 are covered with a protective insulating film 16. The n-type InP clad layer 12 and the p-type InP clad layer 14 are exposed from openings of the protective insulating film 16. The p-type electrode pads 41p and 42p and the n-type electrode pads 41n and 42n are formed on the chip surface. The p-type electrode pads 41p and 42p are connected to the p-type InP clad layer 14 through the openings of the protective insulating film 16. The n-type electrode pads 41n and 42n are connected to the n-type InP clad layer 12 through the openings of the protective insulating film 16. In this manner, two EA modulators 41 and 42 having different polarities can be constituted within the same chip.

In the present embodiment, only one EA modulator is connected to each of the output terminals 71 and 72 of the EA driver 70. It is therefore possible to prevent degradation of the modulation bandwidth as in the third embodiment.

Note that the technical features described in the above embodiments may be combined as appropriate.

### REFERENCE SIGNS LIST

10 semiconductor optical integrated device, 11 semi-insulating InP substrate, 12 n-type InP clad layer, 13 light-absorbing layer, 14 p-type InP clad layer, 15 trench, 21, 22 laser, 30 demultiplexer, 41 EA modulator, 41n n-type electrode pad, 41p p-type electrode pad, 42 EA modulator, 42n n-type electrode pad, 42p p-type electrode pad, 50 multiplexer, 60 temperature detector, 62 EA selection control circuitry, 64 laser selection control circuitry, 70 EA driver, 71, 72 output terminal, 80 signal, 100 optical semiconductor device, 16 protective insulating film, 200, 300, 400 optical semiconductor device

1. An optical semiconductor device comprising:
at least one laser;
a plurality of EA modulators to which an output of the laser is connected on an input side and which have absorption peak wavelengths different from each other;
a multiplexer to which outputs of the plurality of EA modulators are connected on an input side and to which a waveguide is connected on an output side;
a temperature detector configured to detect a temperature of the laser or the plurality of EA modulators; and
a selection control circuitry configured to switch an EA modulator to operate among the plurality of EA modulators in accordance with a detected temperature of the temperature detector.

2. The optical semiconductor device according to claim 1,
wherein the plurality of EA modulators include a first EA modulator and a second EA modulator,
the second EA modulator has the absorption peak wavelength smaller than the absorption peak wavelength of the first EA modulator at the same temperature, and
the selection control circuitry causes the first EA modulator to operate when the detected temperature is lower than a threshold determined in advance and causes the second EA modulator to operate when the detected temperature is higher than the threshold.

3. The optical semiconductor device according to claim 2,
wherein the selection control circuitry causes the first EA modulator to operate when the detected temperature is in a first temperature range and causes the second EA modulator to operate when the detected temperature is in a second temperature range, and
a range in which the absorption peak wavelength of the first EA modulator changes in the first temperature range at least partially overlaps a range in which the absorption peak wavelength of the second EA modulator changes in the second temperature range.

4. The optical semiconductor device according to claim 1, wherein the selection control circuitry switches drive voltages of the plurality of EA modulators in accordance with the detected temperature.

5. The optical semiconductor device according to claim 1, further comprising:
the one laser; and
a demultiplexer connecting the laser and the plurality of EA modulators, and configured to demultiplex output light of the laser and input the demultiplexed output light to the plurality of EA modulators.

6. The optical semiconductor device according to claim 1, further comprising:
a plurality of the lasers with oscillation wavelengths different from each other,
wherein outputs of the plurality of lasers are respectively connected on input sides of the plurality of EA modulators, and
the selection control circuitry switches a laser to operate among the plurality of lasers in accordance with the detected temperature.

7. The optical semiconductor device according to claim 6,
wherein the plurality of lasers include a first laser and a second laser,
the second laser has the oscillation wavelength smaller than the oscillation wavelength of the first laser at the same temperature, and
the selection control circuitry causes the first laser to operate when the detected temperature is lower than a threshold determined in advance and causes the second laser to operate when the detected temperature is higher than the threshold.

8. The optical semiconductor device according to claim 7,
wherein the selection control circuitry causes the first laser to operate when the detected temperature is in a first temperature range and causes the second laser to operate when the detected temperature is in a second temperature range, and
a range in which the oscillation wavelength of the first laser changes in the first temperature range at least partially overlaps a range in which the oscillation wavelength of the second laser changes in the second temperature range.

9. The optical semiconductor device according to claim 6, wherein the selection control circuitry switches drive currents of the plurality of lasers in accordance with the detected temperature.

10. The optical semiconductor device according to claim 6,
wherein the selection control circuitry includes:
a laser selection control circuitry configured to supply a drive current to one of the plurality of lasers to cause the one of the plurality of lasers to operate in accordance with the detected temperature; and
an EA selection control circuitry configured to supply a drive voltage to one of the plurality of EA modulators to cause the one of the plurality of EA modulators to operate in accordance with the detected temperature.

11. The optical semiconductor device according to claim 6, wherein a drive voltage is supplied to each of the plurality of EA modulators.

12. The optical semiconductor device according to claim 11, further comprising:
an EA driver having an output terminal that outputs the drive voltage,
wherein the plurality of EA modulators are connected in parallel to the output terminal of the EA driver.

13. The optical semiconductor device according to claim 11, further comprising:
an EA driver configured to output a positive phase signal and a reverse phase signal as the drive voltage,
wherein the positive phase signal is applied to one of a first EA modulator and a second EA modulator among the plurality of EA modulators, and
the reverse phase signal is applied to another of the first EA modulator and the second EA modulator.

14. The optical semiconductor device according to claim 13,
wherein the positive phase signal is applied to a p-type electrode of the one of the first EA modulator and the second EA modulator, and
the reverse phase signal is applied to an n-type electrode of the other of the first EA modulator and the second EA modulator.
